(19) United States
(12) Patent Application Publication
(10) Pub. No.: US 2008/0131996 A1
(43) Pub. Date: Jun. 5, 2008

(54) Reverse build-up process for fine bump pitch approach

(76) Inventor: Gene Wu, Dayuan Township (TW)

Correspondence Address: SLATER & MATSIL, L.L.P., 17950 PRESTON ROAD, SUITE 1000, DALLAS, TX, 75252, US

(21) Appl. No.: 11/633,718

(22) Filed: Dec. 5, 2006

(51) Int. Cl. H01L 21/00

(52) U.S. Cl. 438/106

(57) ABSTRACT

A reverse build-up method for forming a package substrate includes forming bumps; forming an interconnect structure connected to the bumps; and forming ball grid array (BGA) balls on the interconnect structure. The BGA balls are electrically connected to the bumps through the interconnect structure. The step of forming the bumps are performed before the steps of forming the interconnect structure and forming the BGA balls.

### TECHNICAL FIELD

This invention relates generally to packaging of semiconductor dies, and more particularly to reverse build-up methods for packaging semiconductor dies.

### BACKGROUND

In semiconductor industry, integrated circuits are typically formed on wafers, wherein a plurality of semiconductor chips is formed simultaneously on a same wafer. The semiconductor chips are then sawed from the wafers. Since semiconductor chips are typically small and fragile, they need to be packaged before being used.

FIG. 1 illustrates a conventional package, which includes a semiconductor chip (die) 2 bonded to a package substrate 4, for example, through solder bumps 6. Package substrate 4 includes core 8 and a plurality of interconnect layers built up on both sides of core 8. Die 2 and core 8 are separated by interconnect layers. On an opposite side of package substrate 4 than the side where die 2 is attached, ball grid array (BGA) balls 10 are formed, which are used for connecting the package substrate to external electrical components, such as a motherboard. Die 2 and BGA balls 10 are electrically coupled through metal lines and vias formed in the interconnect layers. Vias 12 are formed in core 8 to make electrical connections from one side of core 8 to another.

The conventional packages suffer drawbacks. First, due to the formation of solder bumps 6 and corresponding solder resist (not shown), the reduction in pitch P1 has reached a limit. It is very difficult to further reduce pitch P1 with existing packaging processes. Currently, the minimum pitch P1 is about 140 μm. Second, die 2 typically has a coefficient of thermal expansion (CTE) of between about 2.3 and 4.2. Core 8, on the other hand, is typically formed of bismaleimide triazine (BT), which has a CTE of about 15. The significant CTE mismatch causes stresses to be applied on die 2 and solder bumps 6 under thermal cycles, which causes warpage of die 2 and/or the failure of solder bump connections. Third, with core 8, the total thickness of the entire package, including BGA balls 10, package substrate 8 and die 2, may reach about 2.3 mm, which will be too thick for future requirements. Therefore, new packaging structures and methods are needed.

### SUMMARY OF THE INVENTION

In accordance with one aspect of the present invention, in a reverse build-up method for forming a package substrate, bumps are first formed. An interconnect structure is then connected to the bumps. Ball grid array (BGA) balls are formed on the interconnect structure. The BGA balls are electrically connected to the bumps through the interconnect structure. The step of forming the bumps are performed before the steps of forming the interconnect structure and the BGA balls.

In accordance with another aspect of the present invention, a method for packaging a die includes providing a disposable layer. Openings are formed extending from a top surface of the disposable layer into the disposable layer. The openings are then filled with conductive materials to form bumps. An interconnect structure is formed on the disposable layer, followed by removing the disposable layer to expose the bumps. The die is attached onto the bumps.

In accordance with yet another aspect of the present invention, a method for forming a package substrate includes providing a copper foil. Openings are formed extending from a top surface of the copper foil into the copper foil. The openings are filled with conductive materials to form bumps. An interconnect structure comprising a plurality of interconnect layers on the disposable layer is formed, wherein each of the interconnect layers comprises vias and copper lines in Ajinimoto buildup film (ABF). Ball grid array (BGA) balls are formed on the interconnect structure, wherein the BGA balls are electrically connected to the bumps through the interconnect structure. The copper foil is then removed to expose the bumps.

The advantageous features of the present invention include reduced pitch of bumps that are attached to the die, reduced number of interconnect layers, hence reduced thickness of packages substrates, reduced insertion loss, and reduced production cost.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional package, including a core and interconnect layers formed on both sides of the core; and

FIGS. 2 through 15 are cross-sectional views of intermediate stages in the manufacturing of an embodiment of the present invention.

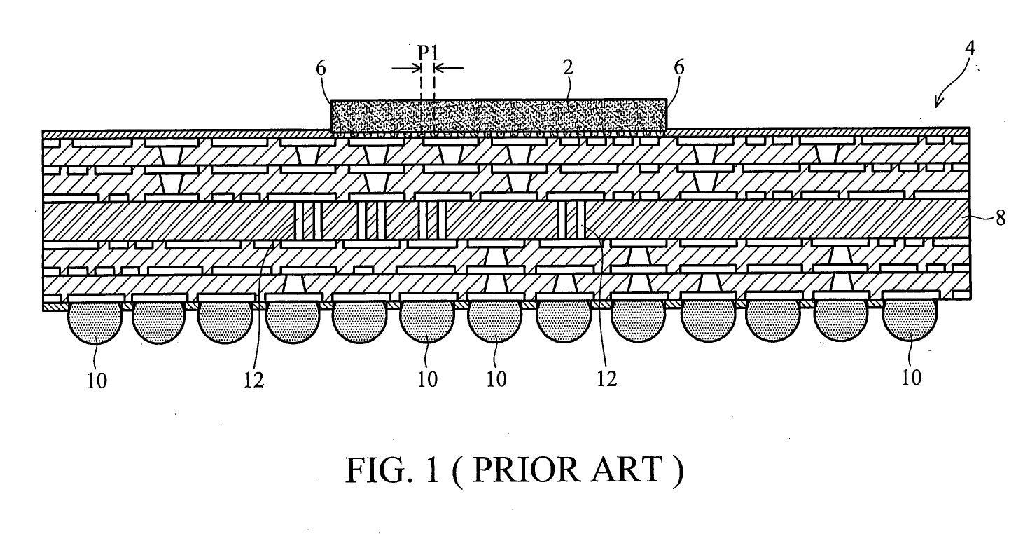

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

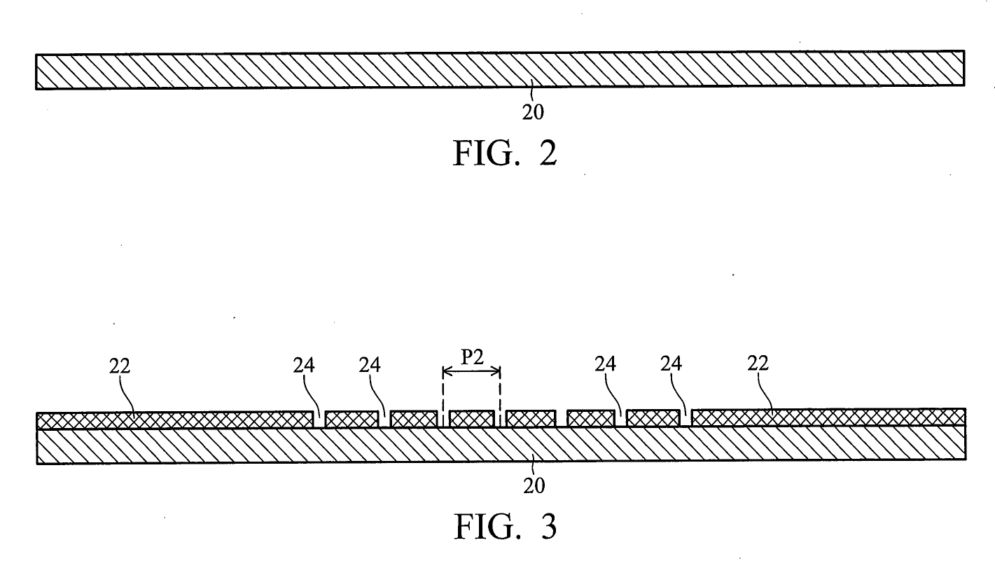

An embodiment of the present invention is illustrated in FIGS. 2 through 15. Throughout the various views and illustrative embodiments of the present invention, like reference numbers are used to designate like elements. Referring to FIG. 2, the packaging process starts with a disposable layer 20. In the preferred embodiment, disposable layer 20 is a copper foil, hence is referred to as copper foil 20 throughout the description. In other embodiments, disposable layer 20 is formed of other materials having different etching characteristics from the bumps that are subsequently formed therein. Exemplary materials of disposable layer 20 include Cu, Al, and Ni. Copper foil 20 preferably has a thickness of between about 2 mils and about 12 mils, although different thicknesses can be used.

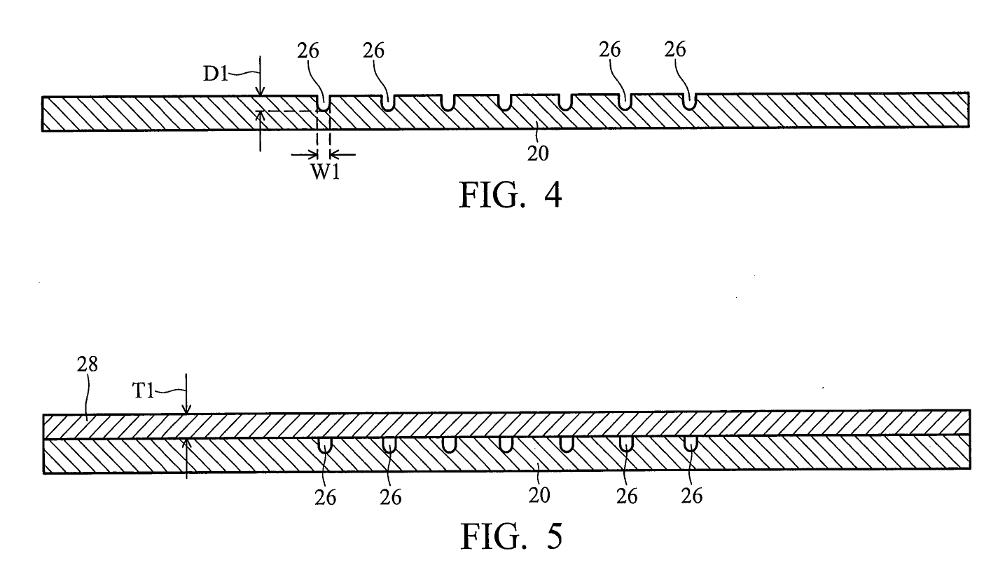

FIGS. 3 and 4 illustrate an image transfer process. Referring to FIG. 3, dry film 22 is attached onto copper foil 20, and is then patterned to form openings 24. In an exemplary embodiment, pitch P2 of openings 24 is less than about 140 μm, and more preferably about 120 μm. An etching process is then performed to form openings 26 in copper foil 20, as shown in FIG. 4. Openings 26 preferably have a depth D1 of greater than about 15 μm. Width W1 of opening 26 is preferably less than about 100 um, and more preferably about 60 μm. Dry film 22 is then removed.

Referring to FIG. 5, dielectric layer 28 is formed on the previously formed structure. In the preferred embodiment, dielectric layer 28 comprises an organic material such as Ajinimoto buildup film (ABF). However, other common materials such as Prepreg and resin coated copper (RCC) can be used. In the case dielectric layer 28 is formed of ABF, the ABF film is laminated on the structure shown in FIG. 4. Heat and pressure may be applied to the laminated film to soften it so that a flat top surface is formed. In the resulting structure, dielectric layer 28 has a thickness T1 of between about 30 μm and about 50 μm, and more preferably about 30 μm.

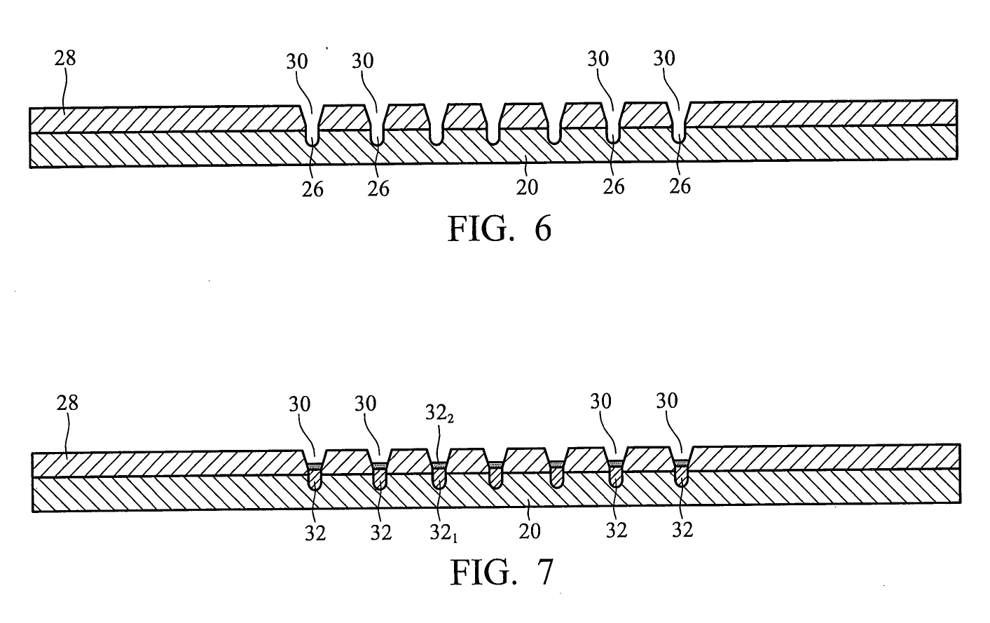

Openings 30 are then formed in dielectric layer 28 to expose openings 26, as shown in FIG. 6. Preferably, openings 30 are formed by laser drilling and desmear.

FIG. 7 illustrates the formation of bumps 32, which are preferably formed by selectively filling conductive materials into openings 26. In an embodiment of the present invention, a tin (Sn) layer 32, is selectively plated into openings 26, followed by the plating of nickel (Ni) layer 32₂. In other embodiments, other commonly used bump materials such as solder alloys can be filled into openings 26 to form layer 32₁, and barrier layer 32₂ (such as a nickel layer) is formed when necessary to prevent subsequently deposited copper from forming an alloy with the bump materials. The filling methods include electro-plating and electroless plating.

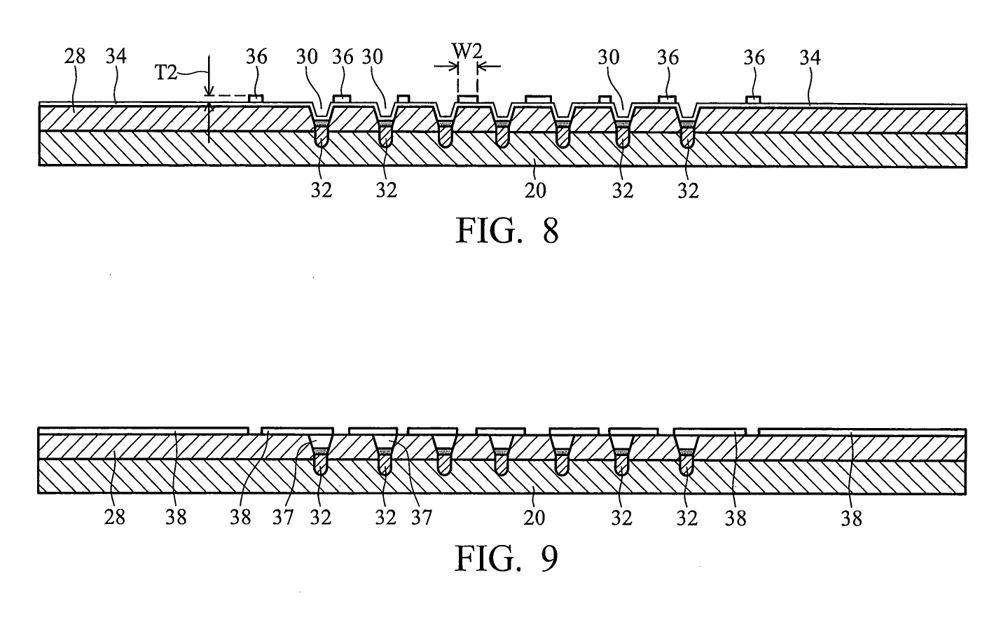

Referring to FIG. 8, a thin seed layer 34, preferably comprising copper, is formed on surfaces of dielectric layer 28 and bumps 32, wherein electroless plating is preferably performed. Thin seed layer 34 may have a thickness of less than about 0.8 μm. Dry film 36 is then formed on seed layer 34, followed by a patterning process to form openings, through which bumps 32 are exposed. The thickness T2 of dry film 36 is preferably determined by the desired thickness of the subsequently formed conductive lines. In an exemplary embodiment, thickness T2 of dry film 36 is between about 25 μm and about 35 μm, and more preferably about 25 μm. In an exemplary embodiment, the width W2 of the remaining dry film may be as small as about 20 μm.

Referring to FIG. 9, conductive patterns 38, which may include conductive lines and pads, are formed, for example, by selectively electro-plating on the portions of the seed layer 34 not covered by dry film 36. Vias 37 are also formed in the remaining portions of openings 30. Conductive patterns 38 are preferably formed of copper or copper alloys, although other commonly used metals such as silver and nickel can also be used. Top surfaces of conductive patterns 38 are preferably level with, although they can be slightly lower than, the top surface of dry film 36. After the formation of conductive patterns 38, dry film 36 and the portions of seed layer 34, underlying dry film 36, are removed. In an exemplary embodiment, dry film 36 is removed in an alkaline solution, and the portions of seed layer 34 under dry film 36 are removed by a flash etching. As a side effect, a thin surface layer is also removed from conductive patterns 38 by the flash etching.

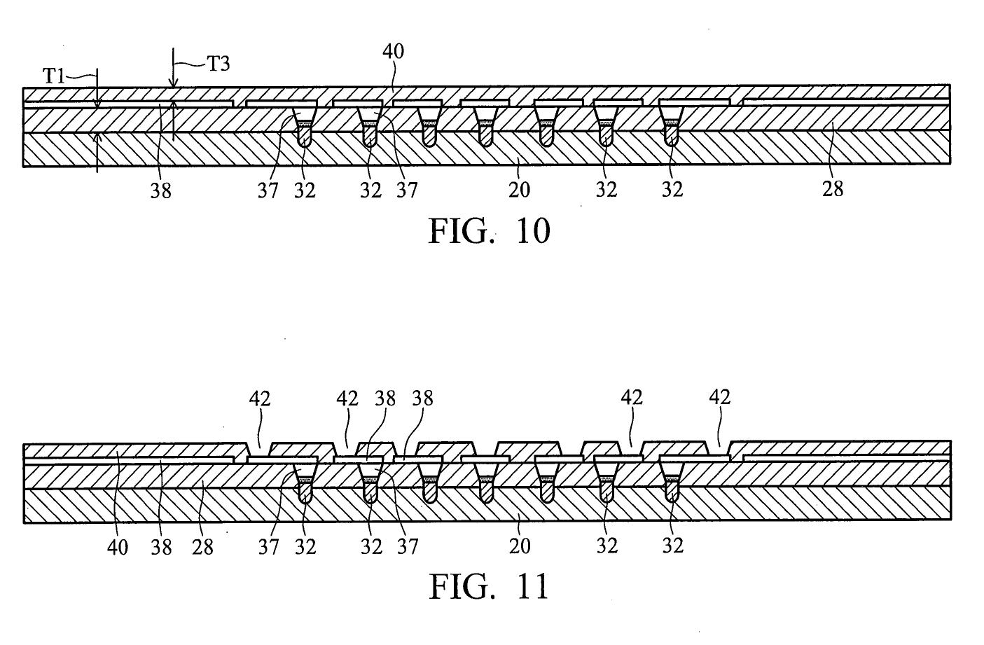

Referring to FIG. 10, dielectric layer 40 is blanket formed, which may be formed of essentially the same materials (such as ABF) and using essentially same methods as dielectric layer 28. During the laminating process, heat and pressure may be applied to help dielectric layer 40 fill the spaces left by the removed dry film 36. A thickness T3 from a top surface of conductive patterns 38 to a top surface of dielectric layer 40 is preferably close to thickness T1, which may be about 30 μm.

Openings 42 are then formed to expose conductive patterns 38, for example, by laser drilling, as shown in FIG. 11. In the subsequent process steps, a thin seed layer (not shown), which is essentially the same as thin seed layer 34 (refer to FIG. 8), is formed. A dry film (not shown) is then formed on the seed layer, followed by a patterning process, which forms openings through which conductive patterns 38 are exposed.

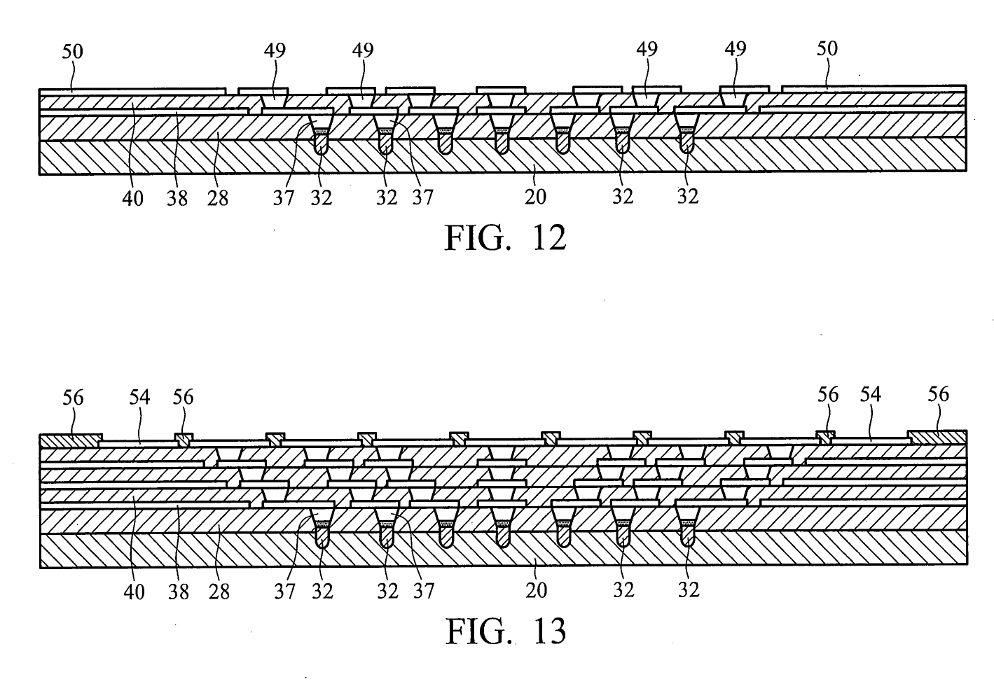

FIG. 12 illustrates the formation of conductive patterns 50, which comprise essentially the same material, and may be formed using essentially the same methods, as conductive patterns 38. After the formation of conductive patterns 50, the dry film and the portions of the seed layer underlying the dry film are removed. The process details for forming conductive patterns 50 are essentially the same as forming conductive patterns 38, thus are not repeated herein. The material filled into openings 42 form vias 49.

Processes are then continued to form more interconnect layers including vias and conductive patterns, and the resulting structure is shown in FIG. 13. The process steps for forming each interconnect layer is essentially the same as shown in FIGS. 11 and 12. Preferably, three to five interconnect layers (including the interconnect layer comprising conductive patterns 38 and underlying vias 37) may be formed, wherein each interconnect layer includes a layer of conductive patterns and underlying vias.

In alternative embodiments, other known methods, such as damascene processes, can be used to form each of the interconnect layers. As is known in the art, damascene processes typically include the steps of forming a dielectric layer and forming openings in the dielectric layer. The openings are filled with a conductive material such as copper or copper alloys. A chemical mechanical polish is then performed to planarize the surface of the conductive material. The remaining portions of the conductive material form vias and conductive patterns.

Referring to FIG. 13 again, bump pads 54 are formed in the top interconnect layer. Solder mask 56 (also referred to as solder resist) is also formed, which may have a thickness of about 20 μm. Solder resist openings (SRO) are then formed, exposing underlying bump pads 54.

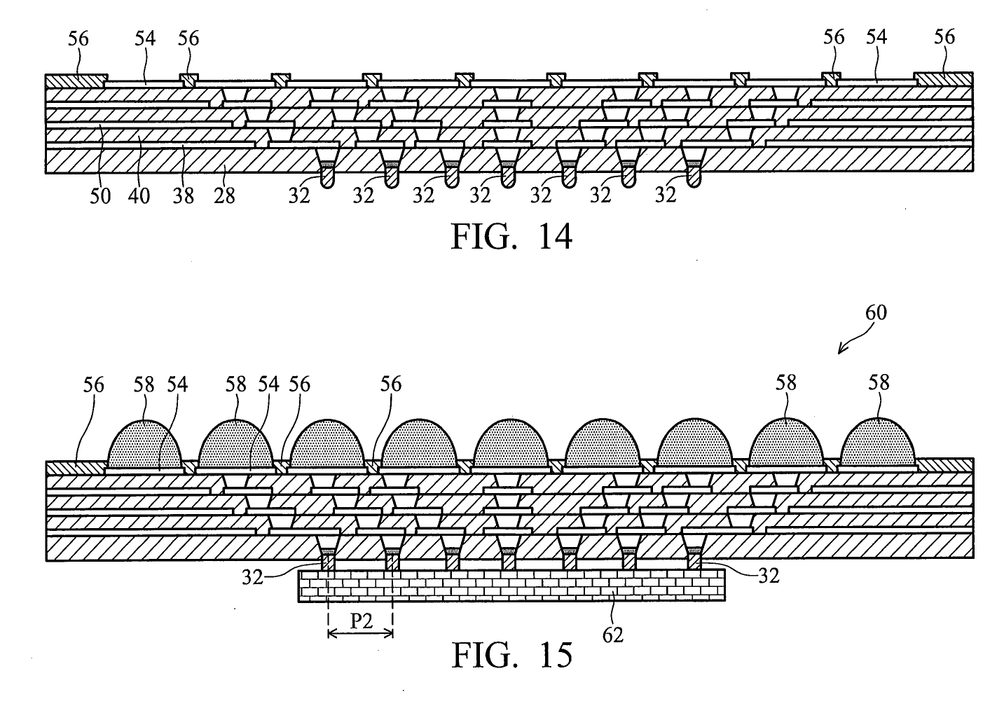

FIG. 14 illustrates the removal of copper foil 20, which is preferably etched using an etchant that attacks copper foil 20 but not bumps 32. As a result, bumps 32 are exposed. Package substrate 60 is thus formed.

Ball grid array (BGA) balls 58 are then formed on bump pads 54, as is illustrated in FIG. 15. The details for forming bump pads 54, solder mask 56 and BGA balls 58 are well known in the art, thus are not repeated herein.

In FIG. 15, die 62 is attached to package substrate 60 through bumps 32. As is known in the art, bumps 32 are re-flowed to form a good contact with under bump metallurgies (UBMs, not shown) in die 62.

An advantageous feature of the present invention is that due to the reverse build-up process, no solder resist is needed for bumps 32, and hence pitch P2 (refer to FIGS. 3 and 15) of die 62 may be reduced. In an exemplary embodiment, pitch P2 is about 120 μm. In conventional package structures, however, solder bumps are used for connecting dies and packages substrates, which requires a solder resist to be formed. Correspondingly, the minimum pitches are at least 140 μm.

The embodiments of the present invention have some other advantageous features. Due to the removal of a core from the package substrate, electrical signals are routed through interconnect layers more efficiently, and less space in interconnect layers is wasted. Accordingly, the number of interconnect layers may be reduced from eight layers in conventional package substrates to five layers, and even three layers, in the present invention. The thickness of overall package substrate is also reduced accordingly, to, for example, between about 7 mils and about 12 mils. In addition, the removal of cores from the middle of the interconnect layers will reduce the package inductances and insertion losses. The cost related to the core, including core material, mechanical drilling, plating through holes, ink plugging, grinding and patterning, is also saved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1-7. (canceled)

8. A method for packaging a die, the method comprising:
providing a copper foil;
forming openings extending from a top surface of the copper foil into the copper foil, wherein the openings have a depth less than a thickness of the copper foil;
filling the openings with conductive materials to form bumps;
forming an interconnect structure on the copper foil;
removing the copper foil to expose the bumps; and
attaching the die on the bumps.

9. (canceled)

10. The method of claim 8, wherein the step of filling the openings comprises: filling a bump material into the openings; and forming a conductive baffler layer on the bump material.

11. The method of claim 10, wherein the bump material comprises tin, and the conductive barrier layer comprises nickel.

12. The method of claim 8, wherein the step of forming the interconnect structure comprises:
forming a dielectric layer;
forming additional openings in the dielectric layer:
forming a seed layer;
forming and patterning a dry film, wherein the additional openings are exposed through spaces in the dry film;
plating a conductive material to fill the additional opening and the spaces in the dry film; and
removing the dry film and portions of the seed layer underlying the dry film.

13. The method of claim 12, wherein the dielectric layer comprises Ajinomoto buildup film (ABF).

14. The method of claim 8 further comprising forming ball grid array (BGA) balls on the interconnect structure, wherein the BGA balls are electrically connected to the bumps through the interconnect structure.

15. The method of claim 8, wherein the interconnect structure is free from cores.

16. The method of claim 8, wherein the openings have a pitch of less than 140 μm.

17. A method for forming a package substrate, the method comprising:
providing a copper foil;
forming openings extending from a top surface of the copper foil into the copper foil, wherein the openings have a depth less than a thickness of the copper foil;
filling the openings with conductive materials to form bumps;
forming an interconnect structure comprising a plurality of interconnect layers on the copper foil, wherein each of the interconnect layers comprises vias and copper lines in an Ajinomoto buildup film (ABF);
forming ball grid array (BGA) balls on the interconnect structure, wherein the BGA balls are electrically connected to the bumps through the interconnect structure; and
removing the copper foil to expose the bumps.

18. The method of claim 17, wherein the step of forming the interconnect structure comprises:
attaching an ABF over the copper foil;
forming additional openings in the ABF:
electroless plating a copper seed layer in the additional openings;
forming a patterned dry film, wherein the additional openings are exposed through spaces in the patterned dry film;
plating copper to fill the additional openings and the spaces in the patterned dry film; and
removing the dry film and portions of the copper seed layer underlying the dry film.

19. The method of claim 17, wherein the interconnect structure is free from cores and has less than six interconnect layers.

20. The method of claim 17, wherein the openings have a pitch of about 120 μm.

21. The method of claim 8, wherein the step of forming the bumps comprises: selectively forming a plurality of tin layers, each in one of the openings; and selectively forming a plurality of nickel layers, each on one of the plurality of tin layers.

22. The method of claim 21, wherein the plurality of tin layers fully fill the openings.

23. The method of claim 8, wherein the step of forming the bumps comprises:
selectively forming a plurality of solder alloys, each in one of the openings; and
selectively forming a plurality of nickel layers, each on one of the plurality of solder alloys.

24. The method of claim 17, wherein the step of forming the bumps comprises: selectively forming a plurality of tin layers, each in one of the openings; and selectively forming a plurality of nickel layers, each on one of the plurality of tin layers.

25. The method of claim 24, wherein the plurality of tin layers fully fill the openings.

26. The method of claim 17, wherein the step of forming the bumps comprises:
selectively forming a plurality of solder alloys, each in one of the openings; and
selectively forming a plurality of nickel layers, each on one of the plurality of solder alloys.
